(19) United States
(12) Patent Application Publication
(10) Pub. No.: US 2008/0191193 A1
(43) Pub. Date: Aug. 14, 2008

(54) IN SITU MODIFICATION OF GROUP IV NANOPARTICLES USING GAS PHASE NANOPARTICLE REACTORS

(76) Inventors: Xuegeng Li, Sunnyvale, CA (US); Elena Rogojina, Los Altos, CA (US); David Jurbergs, Austin, TX (US); Damian Aherne, Dublin (IE)

Correspondence Address: Foley & Lardner LLP, 150 East Gilman Street, Madison, WI, 53701-1497, US

(21) Appl. No.: 11/967,568

(22) Filed: Dec. 31, 2007

Related U.S. Application Data
(60) Provisional application No. 60/881,869, filed on Jan. 22, 2007.

(51) Int. Cl. H01L 29/12; H01L 21/20

(52) U.S. Cl. 257/14; 438/478; 257/E21.09; 257/E29.071

(57) ABSTRACT

A method for creating an organically capped Group IV semiconductor nanoparticle is disclosed. The method includes flowing a Group IV semiconductor precursor gas into a chamber. The method also includes generating a set of Group IV semiconductor precursor radical species from the Group IV semiconductor precursor gas with a laser pyrolysis apparatus, wherein the set of the Group IV semiconductor precursor radical species nucleate to form the Group IV semiconductor nanoparticle; and flowing an organic capping agent precursor gas into the chamber. The method further includes generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

### CROSS-REFERENCE TO RELATED APPLICATIONS

This application claims the benefit of U.S. Pat. No. 60/881,869 filed Jan. 1, 2007, entitled IN SITU MODIFICATION OF GROUP IV NANOPARTICLES USING GAS PHASE NANOPARTICLE REACTORS, the entire disclosure of which is incorporated by reference.

### FIELD OF DISCLOSURE

This disclosure relates to methods for the in situ modification of Group IV nanoparticles.

### BACKGROUND

Group IV nanoparticles have proven useful in a variety of applications for a wide selection of optoelectronic devices. However, due to problems associated with the reactivity of Group IV nanoparticle, and hence the stability of Group IV nanoparticle materials, effort has been taken in the art to address the issue of stabilizing Group IV nanoparticles for real world applications.

One example of an approach to increasing the surface stability and hence the quality of photoluminescence of silicon nanoparticles (i.e., nanoparticles that are about 1.0 nm to about 4.0 nm in diameter that emit in the visible portion of the electromagnetic spectrum) has been to passivate the surfaces of the nanoparticles. For some applications, thermal oxidation of the silicon nanoparticle surfaces has proven effective at passivating the nanoparticles. However, for many optoelectronic applications, passivation by oxidation is not appropriate.

An alternative to passivation by surface oxidation is the formation of an organic passivation layer. For example, an extensive review of formation of organic passivation layers on flat and porous bulk surfaces of silicon and germanium surfaces can be found in J. M. Buriak, Chem. Rev., vol. 102, pp. 1271-1308 (2002). The insertion reaction of an unsaturated organic species, such as an alkene or alkyne at a hydrogen-terminated Group IV semiconductor surface site has been known for some time. As detailed in the Buriak review, when the Group IV semiconductor material is silicon, the reaction is referred to as hydrosilylation. In general, this reaction forms a Si—C bond and has been shown to date to provide bulk silicon semiconductor materials some level of protection against chemical attack from certain chemicals.

More specifically, with respect to Group IV nanoparticles, the passivation of colloidal dispersions of silicon nanocrystals harvested from porous silicon wafers using hydrosilylation has been demonstrated (Lars H. Lie, et. al., Journal of Electroanalytical Chemistry, 538-539, pp. 183-190 (2002)). However, the surfaces of such Group IV nanomaterials do not have the integrity required for use in range of optoelectronic devices. This is apparent in that silicon nanoparticles so far reported with organic passivation layers have produced Group IV nanoparticles with poor quantum yields (˜10% or less) and photoluminescent intensities that are not stable over substantial periods of time.

As covered in the above mentioned review, in the context of hydrosilylation using electrografting of porous bulk silicon surfaces, it has been suggested that oxygen in the solvents used during the hydrosilylation reaction may compete with the binding of alkynes to porous silicon solid. Still, even approaches taking the precaution of using oxygen-free solvents during hydrosilylation of silicon nanoparticles have not proven to overcome the surface stability problems associated with Group IV nanoparticles (see for example Swihart et al. US 2004/0229447, Nov. 8, 2004).

Still other approaches suggested for stabilizing Group IV nanoparticles includes a stable shell layer around a Group IV nanoparticle core. However, producing sizable quantities of quality core/shell material has proven to be difficult. Thus, there is a need in the art for approaches to stabilizing Group IV nanoparticles, and methods of producing such materials.

### SUMMARY OF THE INVENTION

The invention relates, in one embodiment, to a method for creating an organically capped Group IV semiconductor nanoparticle. The method includes flowing a Group IV semiconductor precursor gas into a chamber. The method also includes generating a set of Group IV semiconductor precursor radical species from the Group IV semiconductor precursor gas with a laser pyrolysis apparatus, wherein the set of the Group IV semiconductor precursor radical species nucleate to form the Group IV semiconductor nanoparticle; and flowing an organic capping agent precursor gas into the chamber. The method further includes generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

### BRIEF DESCRIPTION OF THE DRAWINGS

FIG. 1 shows a series of Fourier Transform Infrared (FTIR) spectra comparing silicon nanoparticles prepared using different conditions in a gas phase reactor, in accordance with the invention;

FIG. 2 is a generalized schematic of an embodiment of an apparatus for the synthesis of embodiments of in situ modified Group IV nanoparticles, in accordance with the invention;

FIG. 3 is a schematic of an embodiment of a two-stage RF plasma reactor for the synthesis of embodiments of in situ modified Group IV nanoparticles, in accordance with the invention;

FIG. 4 is a schematic of an embodiment of a two-stage laser pyrolysis reactor for the synthesis of embodiments of in situ modified Group IV nanoparticles, in accordance with the invention; and

FIG. 5 is a representation for the demonstration of factors impacting the synthesis of embodiments of in situ modified Group IV nanoparticles using an embodiment of a two-stage laser pyrolysis reactor, in accordance with the invention.

### DETAILED DESCRIPTION

What is disclosed herein provides for embodiments of in situ modified Group IV nanoparticles prepared using gas phase nanoparticle reactors. In some embodiments, the in situ modified Group IV nanoparticle core materials are modified with a shell layer. As will be discussed in more detail subsequently, such core/shell nanoparticles may have cores of silicon, germanium, and alpha-tin Group IV material; or alloys thereof. The core/shell in situ modified Group IV nanoparticles may be doped. The shell may be of a variety of Group IV materials and combination thereof, or other materials, such as, for example, but not limited by, a variety of oxides, nitrides, carbides, and sulfides. In still other embodiments, a stable organic passivation layer may be formed in situ; either on a Group IV nanoparticle material, or on a core/shell nanoparticle.

It is contemplated that Group IV semiconductor nanoparticles may be used in a variety of applications. Due to the luminescent properties of small nanoparticles, silicon and germanium nanoparticles have been contemplated for use in light-emitting applications, including use as phosphors for solid-state lighting, luminescent taggants for biological applications, security markers and related anti-counterfeiting measures. Other potential applications include a variety of optoelectronic devices, such as light-emitting diodes, photodiodes, photovoltaic cells, and sensors that utilize their unique optical and semiconductor properties. Because of the ability to produce colloidal forms of semiconductor nanoparticles, these materials offer the potential of low-cost processing, such as printing, that is not possible with conventional semiconductor materials.

Group IV nanoparticles have an intermediate size between individual atoms and macroscopic bulk solids. In some embodiments, Group IV nanoparticles have a size on the order of the Bohr exciton radius (e.g., 4.9 nm for silicon), or the de Broglie wavelength, which allows individual Group IV nanoparticles to trap individual or discrete numbers of charge carriers, either electrons or holes, or excitons, within the particle. The Group IV nanoparticles may exhibit a number of unique electronic, magnetic, catalytic, physical, optoelectronic and optical properties due to quantum confinement and surface energy effects. For example, Group IV nanoparticles exhibit luminescence effects that are significantly greater than, as well as melting temperatures of nanoparticles substantially lower than the complementary bulk Group IV materials.

These unique effects vary with properties such as size and elemental composition of the nanoparticles. For instance, as will be discussed in more detail subsequently, the melting of germanium nanoparticles is significantly lower than the melting of silicon nanoparticles of comparable size. With respect to quantum confinement effects, for silicon nanoparticles, the range of nanoparticle dimensions for quantum confined behavior is between about 1 nm to about 15 nm, while for germanium nanoparticles, the range of nanoparticle dimensions for quantum confined behavior is between about 1 nm to about 35 nm, and for alpha-tin nanoparticles, the range of nanoparticle dimensions for quantum confined behavior is between about 1 nm to about 40 nm. In another example, some embodiments of Group IV nanoparticles exhibit photoluminescence effects that are significantly greater than the photoluminescence effects of macroscopic materials having the same composition. Such these photoluminescence effects vary as a function of the size of the nanoparticle, so that light emitted, and hence color emitted in the visible portion of the electromagnetic spectrum is a quantum confinement effect that varies with nanoparticle size.

As used herein, the term “Group IV nanoparticle” generally refers to hydrogen terminated Group IV nanoparticles having an average diameter between about 1.0 nm to 100.0 nm, and composed of silicon, germanium, and alpha-tin, or combinations thereof. As will be discussed subsequently, some embodiments of Group IV nanoparticles are doped. With respect to shape, embodiments of Group IV nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group IV nanoparticle materials may be created by varying the attributes of composition, size, shape, and crystallinity of Group IV nanoparticles. Exemplary types of Group IV nanoparticle materials are yielded by variations including, but not limited by:

1) single or mixed elemental composition; including alloys, core/shell structures, doped nanoparticles, and combinations thereof; 2) single or mixed shapes and sizes, and combinations thereof; and 3) single form of crystallinity or a range or mixture of crystallinity, and combinations thereof.

It is contemplated that suitable quality Group IV nanoparticles are used as starting materials for the uses and compositions disclosed herein. Particle quality includes, but is not limited by, particle morphology, average size and size distribution. For embodiments of disclosed in situ modified Group IV nanoparticles, suitable nanoparticle materials useful as starting materials have distinct particle morphology, with low incidence of particle clumping, agglomeration, or fusion. As mentioned previously, the properties that are imparted for Group IV nanoparticles are related closely to the particle size. In that regard, for many applications, a monodisperse population of particles of specific diameter is also indicated.

For the Group IV nanoparticles, the surface area to volume ratio, which is inversely proportional to radius, is in the range of a thousand times greater than for colloids in the 1.0 micron range. These high surface areas, as well as other factors, such as, for example, the strain of the Group IV atoms at curved surfaces, are conjectured to account for what the inventors have observed, which has not been generally reported in the literature, as the extraordinary reactivity of the Group IV nanoparticles. As a result of this observation, embodiments of the disclosed in situ modified Group IV nanoparticle materials are maintained in an inert environment until they are stably processed, so that for the target application the material so produced has the highest quality for the intended use.

For example, stabilized luminescence is observed for in situ modified Group IV nanoparticles that have been organically capped. Phenomena such as high quantum yield and intensity of photoluminescence emitted from such embodiments of organically capped Group IV nanoparticles is observed. With respect to semiconductor properties, the inventors' have observed that by keeping embodiments of the native Group IV nanoparticles in an inert environment from the moment the particles are formed through the formation of Group IV semiconductor thin films, that such thin films so produced have properties characteristic of native bulk semiconductor materials. In that regard, such thin films are formed from materials for which the spectral absorbance, photovoltaic and photoconductive properties are well characterized. This is in contrast, for example, to the use nanoparticles mixed with organic modifiers. In some such modifications, the Group IV nanoparticle materials are significantly oxidized. The use of these types of nanoparticle materials produces hybrid thin films, which hybrid thin films do not have as yet the same desirable properties as traditional Group IV materials.

The first step for producing embodiments of the disclosed in situ modified Group IV nanoparticles is to produce quality nanoparticles in an inert environment. For the purposes of this disclosure, an inert environment is an environment in which there are no fluids (i.e., gases, solvents, and solutions) that react in such a way that they would negatively affect properties such as the semiconductor, photoelectrical, and luminescent properties of the Group IV nanoparticles. In that regard, an inert gas is any gas that does not react with embodiments of in situ modified Group IV nanoparticles in such a way that it negatively affects the properties of the in situ modified Group IV nanoparticles for their intended use. Likewise, an inert solvent is any solvent that does not react with embodiments of in situ modified Group IV nanoparticles in such a way that it negatively affects the properties of the in situ modified Group IV nanoparticles for their intended use. Finally, an inert solution is a mixture of two or more substances that does not react with in situ modified Group IV nanoparticles in such a way that it that it negatively affects the properties of the in situ modified Group IV nanoparticles for their intended use.

Accordingly, the in situ Group IV nanoparticles may be made in any suitable gas phase reactor according to any suitable gas phase method provided they are formed in an environment that is substantially inert. Examples of suitable gas phase reactors include, for example, but not limited by RF plasma and laser pyrolysis reactors. Examples of inert gases that may be used to provide an inert environment include nitrogen and the rare gases, such as argon. Though not limited by defining inert as only oxygen-free, since other fluids may react in such a way that they negatively affect the semiconductor, photoelectrical, and luminescent properties of the in situ modified Group IV nanoparticles, it has been observed that a substantially oxygen-free environment is indicated for producing suitable Group IV nanoparticles. As used herein, the terms “substantially oxygen free” in reference to environments, solvents, or solutions refer to environments, solvents, or solutions wherein the oxygen content has been reduced in an effort to eliminate or minimize the oxidation of the in situ modified Group IV nanoparticles in contact with those environments, solvents, or solutions. As such, the in situ modified Group IV nanoparticles starting materials are fabricated in inert, substantially oxygen-free conditions until they are stably processed.

For some embodiments of in situ modified Group IV nanoparticles used for example in photoluminescent applications, substantially oxygen-free conditions will contain no more than about 100 ppm oxygen (O₂). This includes embodiments where the substantially oxygen-free conditions contain no more than about 1 ppm oxygen and further includes embodiments where the substantially oxygen-free conditions contain no more than about 100 ppb oxygen. For photovoltaic and photoconductive applications of in situ modified Group IV nanoparticles, “inert” refers to environments, solvents, or solutions wherein the oxygen content has been substantially reduced to produce, for example, Group IV semiconductor thin films having no more than 10¹⁷ to 10¹⁹ oxygen per cubic centimeter of Group IV semiconductor thin film. In that regard, if the in situ modified Group IV nanoparticle materials are reactive after preparation, such as for example a silicon/germanium core/shell nanoparticle material, such material should be maintained under vacuum or an inert, substantially oxygen-free atmosphere until it has been stably processed. In another example, some embodiments of inks formulated using such reactive in situ modified Group IV nanoparticle materials are made in anhydrous, deoxygenated solvents or solutions held under vacuum or inert gas to minimize the dissolved oxygen content in the liquid until the nanoparticle material is stably processed.

In one aspect of in situ modified Group IV nanoparticle materials using gas phase reactors, embodiments of core/shell particles can be prepared. For example, in the fabrication of photovoltaic thin films, it is desirable to adjust the band gap of embodiments of Group IV photoconductive thin films. For Group IV nanoparticle materials used to fabricate such thin films, the band gap of silicon is about 1.1 eV, while the band gap of germanium is about 0.7 eV, and for alpha-tin is about 0.05 eV. This may be done through formulations of single or mixed elemental composition of silicon; germanium and tin nanoparticles in core/shell structures, as well as alloys, doped nanoparticles, and combinations thereof. Embodiments of the in situ modified Group IV core/shell nanoparticle materials so formed can be specifically designed to provide the targeted thin film band property. As previously discussed, Group IV nanoparticle core materials can be prepared having a variety of shell materials, for example, but not limited by, carbide, nitride, sulfide, and oxide shell compositions.

In another aspect of in situ modified Group IV nanoparticle materials using gas phase reactors, embodiments of Group IV nanoparticles with a variety of organic passivation layers from a variety of organic capping agents is contemplated. One example of a reaction that is used for creating an organic passivation layer on Group IV nanoparticle materials is an insertion reaction between the hydrogen-terminated Group IV atoms at the nanoparticles surface and alkenes or alkynes. For the in situ modified Group IV nanoparticles of interest, which are silicon, germanium, and tin; and core/shell nanoparticle materials, as well as alloy nanoparticle material thereof, the reaction is referred to as hydrosilylation, hydrogermylation, and hydrostannylation, respectively. In solution, various suitable protocols for this class of insertion reaction are known. Such protocols include the use of a free-radical initiator, thermally induced insertion, photochemical insertion using ultraviolet or visible light, and metal complex mediated insertion. Descriptions of protocols for the above described insertion reaction, and other known reactions for forming Group IV element-carbon bonds may be found in J. M. Buriak, Chem. Rev., vol. 102, pp. 1271-1308 (2002), the entire disclosure of which is incorporated herein by reference.

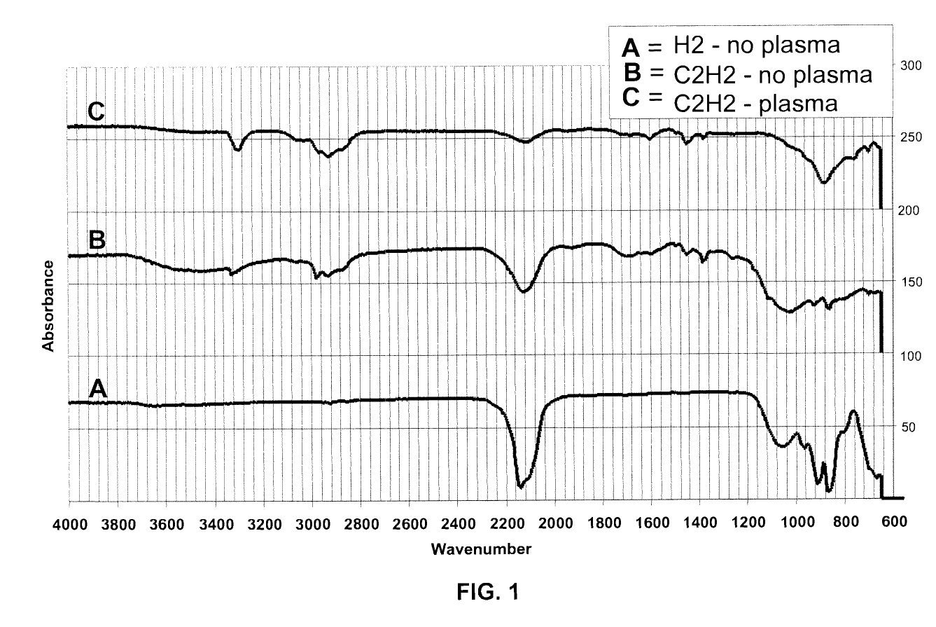

However, embodiments of in situ Group IV nanoparticles disclosed herein are stably passivated with an organic capping agent in the gas phase, using for example, but not limited by, either RF plasma or laser pyrolysis reactors. Without limiting the scope of the invention, one possible explanation for the organic capping of Group IV nanoparticles is that the conditions in such reactors may be optimized to create radical species necessary for reactions such as hydrosilylation to occur between a Group IV atom on a nanoparticle surface, and an organic moiety. The inventors' observations of Group IV nanoparticle reactivity to organic moieties having terminal alkene or alkyne groups in the gas phase are consistent with such an explanation, as can be understood from the Fourier Transform Infrared (FTIR) spectra shown in FIG. 1.

In FIG. 1, the spectra of samples of Group IV nanoparticles subjected to different conditions in a two-stage RF plasma reactor comprised of an RF plasma reactor in the first stage, in series with a second RF reactor configured like the first stage, only without using RF source, as will be discussed in more detail subsequently. In the first-stage reactor, silicon nanoparticles were formed, and then flowed into the second-stage reactor for further modification in a set of experiments for producing core/shell Group IV nanoparticles. The optimization experiments produced some surprising results. In the second stage, ethylene gas was used as a precursor gas for creating silicon carbide. In FIG. 1, FTIR Spectra A is a control in which no ethylene gas or plasma is used in the second-stage reactor, but only a stream of hydrogen gas. FTIR Spectra A of FIG. 1 is characteristic of hydrogen terminated silicon nanoparticles, having bands at 2140 cm⁻¹ (Si—H stretching mode), as well as 950 cm⁻¹ and 860 cm⁻¹ (both Si—H wagging modes). In FTIR Spectra B of FIG. 1, ethylene was flowed into the second-stage reactor, but no plasma was actuated. It is known that ethylene may ethyl adducts in an insertion reaction with hydrogen terminated Group IV materials. In the mid-range of the infrared portion of the electromagnetic spectrum, bands at about 2850 cm⁻¹ to about 3000 cm⁻¹ are indicative of ethyl adducts to silicon, respectively. These bands are evident in FTIR Spectra B, indicative of conditions which are favorable for promotion of the gas phase insertion reaction of an organic moiety having a terminal alkene or alkyne group.

As will be discussed in more detail subsequently, some examples of organic species of interest for the in situ organic capping of Group IV nanoparticle materials include, but are not limited by, simple alkenes and alkynes in the C2-C18 series, as well as substituted alkenes and alkynes. It is contemplated that for some embodiments of Group IV organic-capped nanoparticle materials, more polar organic moieties such as those containing heteroatoms, or amine of hydroxyl groups are indicated, while in other, aromatic groups, such as phenyl, and benzyl groups are indicated.

As has been previously discussed, examples of reactors suitable for preparation of embodiments of in situ modified Group IV nanoparticles include RF plasma reactors and laser pyrolysis reactors.

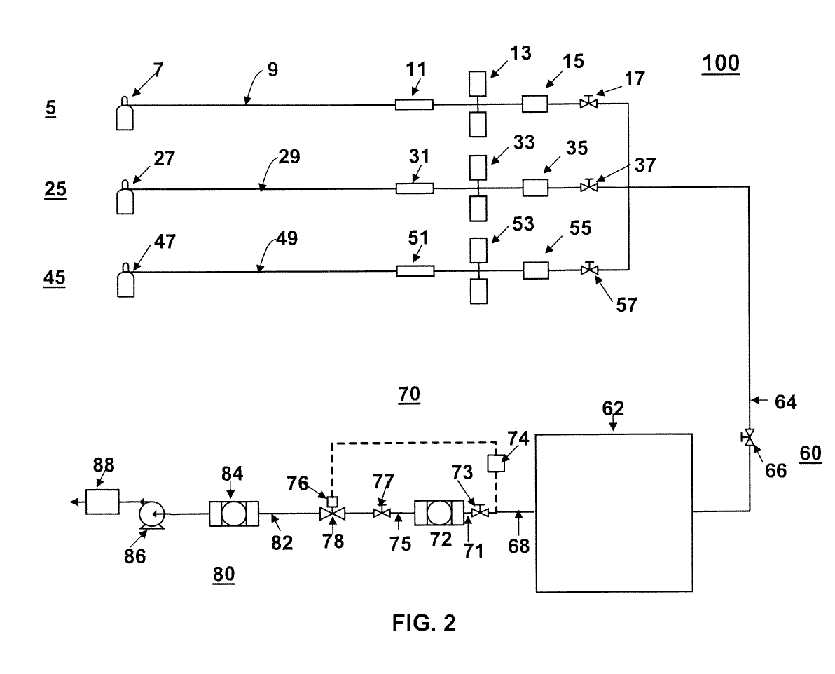

FIG. 2 depicts a generalized schematic of an embodiment of a gas phase reactor apparatus 100 suitable for the fabrication of doped Group IV nanoparticles. For gas phase reactors, a plurality of gas lines as shown in FIG. 2 may be used. Gas line 5 is a generalized gas line for use with nanoparticle reactors, comprised of a gas source 7, a gas line trap 11 for scrubbing oxygen and water from the gas, a gas line analyzer 13 for monitoring oxygen and water levels to ensure that they are effectively removed from the gas phase reactor lines, a gas line mass flow controller 15, and a gas line valve 17. All elements comprising the gas line 5 are in fluid communication with one another through gas line conduit 9. Gas line 5 could be useful as, for example but not limited by, a dopant gas line. As a dopant gas line, then gas line trap 11 is optional for scrubbing oxygen and water from the dopant gas may be used in cases where the dopant gas is not aggressive and can be effectively filtered. Additionally, the gas line analyzer 13 for monitoring oxygen and water levels to ensure that they are effectively removed from the RF plasma reactor lines, may be also optional for the same reason. For example, gas line 25 may be useful for inert make-up gas, and is comprised of an inert gas source 27, an inert gas line trap 31 for scrubbing oxygen and water from the inert gas, an inert gas line analyzer 33 for monitoring oxygen and water levels to ensure that they are effectively removed from the gas phase reactor lines, an inert gas line mass flow controller 35, and an inert gas line valve 37. All elements comprising the inert gas line 25 are in fluid communication with one another through inert gas line conduit 29. In order to make Group IV nanoparticles, gas line 45 is comprised of Group IV semiconductor primary precursor gas source 47, a Group IV primary precursor gas line trap 51 for scrubbing oxygen and water from the Group IV primary precursor gas, a Group IV primary precursor gas line analyzer 53 for monitoring oxygen and water levels to ensure that they are effectively removed from the gas phase reactor lines, a Group IV primary precursor gas line mass flow controller 55, and a Group IV primary precursor gas line valve 57. All elements comprising the Group IV primary precursor gas line 45 are in fluid communication with one another through inert gas line conduit 49.

The gas phase reactor assembly 60 is composed of a gas phase reactor 62, a reactor inlet line 64, a reactor inlet line valve 66, and a reactor outlet line 66. Downstream from the gas phase reactor assembly 60 is the particle collector assembly 70. The particles are collected on a mesh material of a variety of configurations; for example, either as a flat screen or net-shaped. The particles come into the particle collector 72 from particle collector inlet line 71, which has particle collector inlet valve 73. The effluent gas flows from the particle collector 72 out through the particle collector outlet line 75, which has particle outlet valve 77. The pressure control system for particle collector 70 is composed of a pressure sensor 74, controller 76, and a throttle valve, for example, such as a butterfly valve 78. During typical operation, inlet valve 73 and outlet valve 77 are open, but butterfly valve 78 is partially open. As particles are collected in particle collector 72, pressure builds up, and is detected by pressure sensor 74, which through a controller 76 opens butterfly valve 78 to keep the pressure constant. Downstream from the particle collector assembly 70 is the exhaust assembly 80, which of an exhaust line 80, a dust collector 82 and pump 86 with a mist trap 88.

Unless otherwise designated, all valves indicated for the generalized gas phase reactor apparatus 100 are positive shut-off valves, such as ball, diaphragm, bellows, toggle, and plug valves, and all gas line conduits and fittings used are steel. For example, the but not restricted by, the gas lines to the reactor; i.e., up to gas phase reactor inlet line 62 may be 0.250″OD/0.152″ ID stainless steel tubing, while all gas lines from gas phase reactor outlet line 66 to the exhaust are QF40 stainless steel piping.

Where embodiments of gas phase reactor 60 as shown in FIG. 2 are used for doping, a variety of dopant gases are possible for use for creating doped Group IV nanoparticles. For example, n-type Group IV nanoparticles may be prepared using a plasma phase method in the presence of well-known dopant gases such as phosphine, or arsine. Alternatively, p-type semiconductor nanoparticles may be prepared in the presence of dopant gases such as boron diflouride, trimethyl borane, or diborane. With respect to an inert gas sources, noble gases for example, such as argon, helium, and neon and combinations thereof may be used. With respect to the primary precursor gases used for Group IV nanoparticle preparation, primary precursor gases such as silane, disilane, germane, digermane, any of their halide analogs and combinations thereof, are contemplated for use.

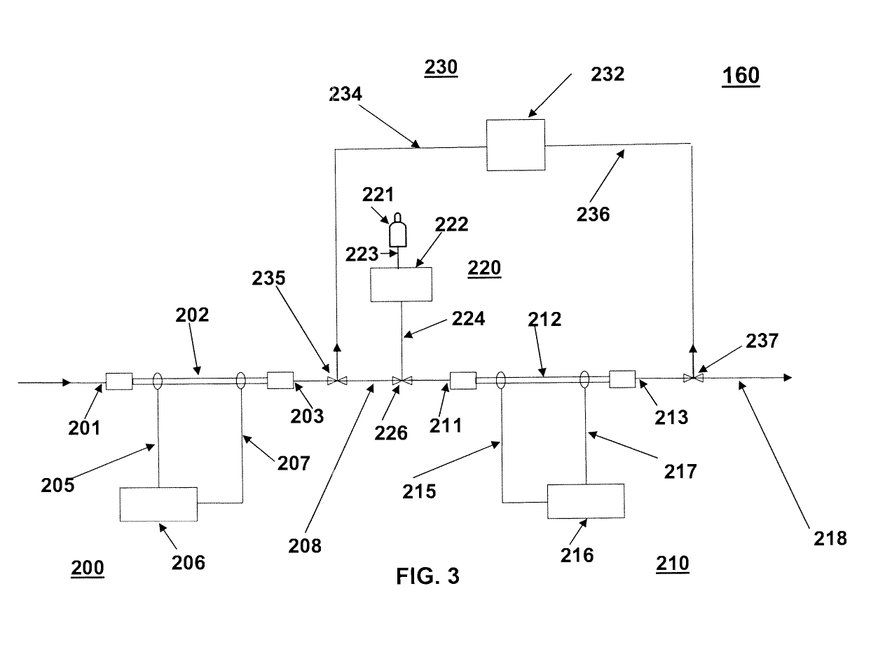

FIG. 3 is a schematic of an embodiment of a two-stage RF plasma reactor assembly 160, which is an embodiment of reactor 60 of FIG. 1. The two-staged RF plasma reactor assembly 160 is composed of a first RF reactor assembly 200, and a second RF plasma assembly 210. The first RF reactor assembly 200 is comprised of a first gas phase reactor chamber 202. The first gas phase reactor chamber 202 has an inlet end 201, which is in fluid communication with a gas reactor inlet line, such as gas reactor inlet line 64 of FIG. 1. The first gas phase reactor chamber has an outlet end 203, which is in fluid communication with the second RF reactor assembly 210 via a first RF reactor assembly line 208. The first RF plasma reactor assembly 200 has a first RF source 206, having a first RF plasma reactor assembly first electrode 205 and a first RF plasma reactor assembly second electrode 207. The first electrode 205 and the second electrode 207 of the first RF plasma reactor assembly 200 are mounted onto the first RF plasma reactor assembly 200 chamber 202 using a ring electrode configuration.

Similarly, second RF reactor assembly 210 is comprised of a second gas phase reactor chamber 212. The second gas phase reactor chamber 212 has an inlet end 211, which is in fluid communication via a first RF reactor assembly line 208. The first gas phase reactor chamber has an outlet end 213, which is in fluid communication with both a particle collector assembly 70 and an exhaust system, such as the exhaust assembly 80 of FIG. 1 via second RF reactor line 218. The second RF plasma reactor assembly 210 has a second RF source 216, having a second RF plasma reactor assembly first electrode 215 and a second RF plasma reactor assembly second electrode 217. As will be discussed in more detail subsequently, for embodiments of Group IV nanoparticles modified with organic capping agents, the RF source 216 is not typically used, so that a dedicated system for organic capping of Group IV nanoparticles may be designed without RF plasma source 216. The first electrode 215 and the second electrode 217 of the second RF plasma reactor assembly 210 are mounted onto the second RF plasma reactor assembly chamber 212 using a ring electrode configuration.

Desirable attributes for the gas phase reactor chambers 202, 212 include, but are not limited by a dielectric material having high transmission of RF frequency with mechanical and chemical stability under plasma conditions. Some examples of such materials include quartz, sapphire, and fumed silica. In some embodiments of RF reactor assemblies 200 and 210, the chambers 202, 212 may be about 0.375″ OD, while in other embodiments the chambers 202, 212 may be about 1.5″. As shown the electrodes 205, 207, 215, 217 are on the exterior of the gas phase reactor chambers 202, 212. A number of metallic materials are suitable for the electrodes, for example, but not limited by copper and stainless steel. The spacing of the electrodes 205, 207, 215, 217 may be about 5 mm to about 30 mm apart for 0.375″ diameter gas phase reactor chambers 202, 212, and may be about 5 mm to about 50 mm apart for 1.5″ diameter gas phase reactor chambers 202, 212. The pressure in the gas phase reactor chambers 202, 212 is kept at between about 0.5 Torr to about 20 Torr. RF reactor sources 206, 216 are sources capable of delivering up to 300 W in power at 13.56 MHz. The power delivered to RF reactor chambers 202, 212 is between about 20 W to about 150 W.

Secondary precursor delivery assembly 220 of FIG. 3 is composed of a secondary precursor assembly gas source 221, and optionally, for some embodiments of in situ modified Group IV nanoparticles, such as Group IV nanoparticles prepared with organic capping, a fluid reservoir 222, which is in fluid communication with secondary precursor assembly gas source 221 through optional fluid reservoir line 223. Both the secondary precursor assembly gas source 221 and fluid reservoir 222 are in fluid communication with secondary RF reaction chamber 216 through secondary precursor assembly gas source line 224, having secondary precursor assembly gas source valve 225.

Optionally, an online analysis assembly 230 of FIG. 3 may also be a component of embodiments of a two-stage RF plasma reactor assembly, such as two-stage RF plasma reactor assembly 160. An analyzer 232, such as a particle counter, or mass spectrometer may be plumbed inline through lines 234 and 236, having analysis assembly valves 235 and 237, respectfully. As shown in FIG. 3, the valving can be two-way to ensure that the analyzer can analyze nanoparticles from both the first stage RF reactor 200 and second stage RF reactor 210.

An example of the preparation of an embodiment of Group IV nanoparticles prepared in a two-stage RF reactor, such as two-stage RF reactor 160 of FIG. 3 is given for doped Group IV nanoparticles prepared in a first stage reactor, such as first stage reactor 200 of FIG. 3, which are subsequently organically capped with a short chained terminal alkene, C2-C9 for example, in a second RF reactor, such as second reactor 210 of FIG. 3. The doped particles may be prepared in an RF reactor described by the combination of the generalized reactor of FIG. 2 and the two-stage RF reactor of FIG. 3. A dopant gas line 5 of FIG. 2 may be a p-type dopant gas line, for the delivery of diborane, while primary precursor gas line 45 of FIG. 2 would be used for a primary precursor gas, such silane. For example, 100 ppm diborane in argon would be in gas source 7 of FIG. 2, while 10% silane in argon would be in source 47 of FIG. 2. The flow rate of the dopant gas may be, for example, between about 60 sccm to about 150 sccm, while the flow rate of the Group IV precursor gas may be between about 15 sccm to about 30 sccm. The first RF plasma reactor chamber, such as first RF reactor chamber 202 FIG. 3 may be quartz tube of about 0.375″ OD, and the electrodes 205, 207 may be copper with a spacing of about 11 mm. Between about 40 W to about 50 W was delivered to the first RF plasma reactor chamber using an RF plasma source, such as first RF plasma source 206 of FIG. 3. The pressure in the first RF plasma reactor chamber 202 may be maintained at between about 5 Torr to about 10 Torr.

As previously mentioned, and in light of the discussion of FIG. 1, for the purpose of modifying Group IV nanoparticles with an organic capping agent, a second reactor without an RF source is typically not used. Therefore, the doped silicon nanoparticles so formed are then passed into a chamber, such as chamber 212 of a second RF reactor 210 of FIG. 3, where the second reactor for organic passivation typically does not have RF plasma source 216, or first and second electrodes 215, 217. Chamber 212 may be quartz tube of about 0.375″ OD. For the gas phase insertion reaction, an inert gas, such as argon would be the secondary precursor assembly gas source, such as secondary precursor assembly gas source 221 of FIG. 3. In this example, secondary gas source would be used to bubble inert gas into a short chain (C5-C9) terminal alkene liquid held in reservoir 222, in order to volatilize the alkene so that it can be passed into secondary RF reactor chamber 212. In the case of C2-C4 alkenes, since these exist as gases, there is no need for reservoir 222. The flow rates of the alkene going into secondary RF reactor chamber 212 may be between about 10 sccm to about 1000 sccm. The stoichiometry of the insertion reaction between the alkene and doped silicon nanoparticle reactants can be controlled by controlling the pressure head of alkene in through controlling the pressure coming from secondary precursor assembly gas source 221. Additionally, an inert solution of an alkene can be prepared using a non-reactive solvent, such as low molecular weight alkanes, such as hexane.

As discussed in the above, given the results discussed for FIG. 1, the second RF source 216 may not be required to activate the reactants for the reaction of the insertion reaction between organic modifier and reactive silicon atoms at the surface of the nanoparticles to proceed, but may be useful for some embodiments of modified Group IV nanoparticles with organic capping agents. Moreover, a second RF reactor 210 of FIG. 3 is required for the formation of core/shell Group IV nanoparticles.

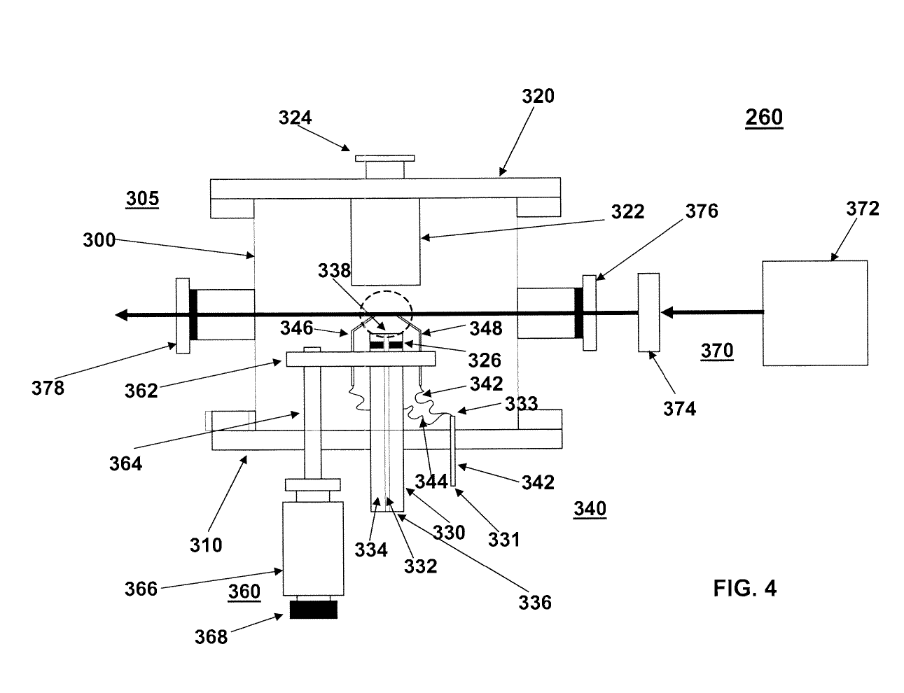

In FIG. 4, a schematic showing the cross-section of an embodiment of a two-stage laser pyrolysis reactor assembly 260, which is another embodiment of reactor 60 of FIG. 2 is shown. The laser pyrolysis reactor body 305 is composed of a casing 300, a bottom plate 310, and top plate 320. The primary precursor conduit or tube 330 is composed of a first inner conduit or tubing 332, and a second outer conduit or tubing 334. The concentric arrangement of inner conduit 332 and outer conduit 334 is maintained by spacer 336, which is made of a porous stainless steel material, and also functions as a filter. The primary precursor conduit 330 has an inlet end 336, which is in fluid communication with a gas reactor inlet line, such as gas reactor inlet line 64 of FIG. 2 and an outlet end 338, which is in fluid communication with laser pyrolysis reactor outlet port 324. A first secondary precursor conduit assembly 340 is composed of secondary precursor conduit of tubing 342, having an inlet end 341, and an outlet end 343. Inlet end 341 may be in fluid communication with a gas source line, such generalized gas line 5 of FIG. 2, or secondary precursor assembly 220 of FIG. 3. Outlet end 343 is in fluid communication with a first secondary precursor nozzle tubing 342, and second secondary precursor nozzle tubing 344. The first secondary precursor nozzle tubing 342 is in fluid communication with a first secondary precursor nozzle 346, while the second secondary precursor nozzle tubing 344 is in fluid communication with a second secondary precursor nozzle 348. A second secondary precursor conduit assembly 350, not shown, and identical with respect to the elements described for first secondary precursor conduit assembly 340 is mounted in an axis orthogonal to the axis in which secondary precursor conduit assembly 340 is mounted, yielding a total of four nozzles symmetrically distributed in the vicinity of particle formation. In this fashion, the secondary precursor gas flow of the secondary precursor gas is evenly distributed around the area in which the particles are formed, which is indicated in the cross-section by the hatched circle. Though two secondary precursor nozzle assembles are disclosed, higher order assemblies and nozzle designs are possible, as would be apparent to one of ordinary skill in the art.

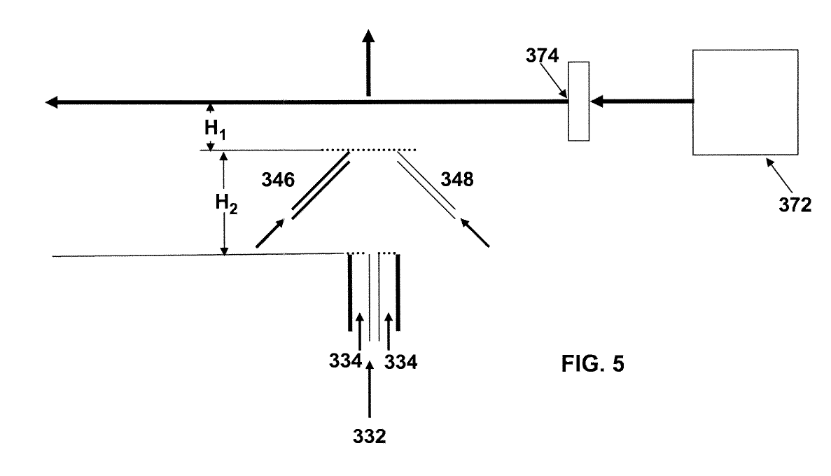

Referring to FIG. 5, the height adjustment of the secondary precursor gas nozzles is important for optimizing the conditions for in situ modification of Group IV nanoparticles. In FIG. 5, two heights are indicated. The first height, H₁ is the height between the secondary precursor nozzles, such as 346, 348, and the center of laser beam, which laser beam is indicated by the arrowed line. It should be noted that this height may also be affected by the adjustment of the laser beam position, as well. The second height, H₂ is the height between the outlet end 338 of primary precursor conduit or tube 330, and the tips of the secondary precursor nozzles, such as 346, 348. In order to adjust the secondary precursor nozzle with great precision and accuracy, secondary precursor nozzle height adjustment assembly 360 is used. Secondary precursor nozzle stage assembly 360 is comprised of stage 362, in which the nozzles, such as 346, 348. Stage 362 is mounted on shaft 364, which is connected to handle 366 and adjustment knob 368. As one of ordinary skill in the art is apprised, such stage assemblies are capable of controlling height adjustments to fractions of a mil, providing highly precise and accurate adjustment of both height, H₁ and height, H₂.

The optical assembly 370 of laser pyrolysis reactor assembly 260 of FIG. 4 is composed of a laser 372, optionally a focusing lens 374 a first optical port 376, and a second optical port 378. The dark line indicates the direction of the laser beam through the laser pyrolysis reactor assembly 260. Orthogonal to the line of sight through first and second optical ports 376, 378 are third and forth optical ports 375, 377 (not apparent in the plane the cross-section of FIG. 4), which are used for operator viewing. The laser needs to have wavelength and power specification suitable for the decomposition of the primary precursor gases in order to form the Group IV nanoparticles. A carbon dioxide (CO₂) laser, having a wavelength of 10.59 microns, and capable of delivering between about 30 W to about 250 W; operating either in the continuous wave or pulsed beam mode, and having an unfocused beam diameter of between about 4 mm to about 8 mm is an example of a laser suitable for use for the laser pyrolysis preparation of Group IV nanoparticles. The window material for the optical ports 375, 376, 377, 378 and other optical material, such as the focusing lens 374 should be durable both chemically and mechanically, and capable of transmission of the light from the laser light source. An example of a suitable window material for use with a CO₂ laser is zinc selenide.

Finally, top plate 320 has particle collector conduit 324, which accumulates and guides the nanoparticles produced towards the laser pyrolysis reactor outlet port 324. The laser pyrolysis reactor outlet port 324 with is in fluid communication with both a particle collector assembly 70 of FIG. 2 and finally, an exhaust system, such as the exhaust assembly 80 of FIG. 2.

### EXAMPLE

A set of grafted Group IV nanoparticles was produced by the two-stage laser pyrolysis reactor assembly 260 as shown in FIG. 4, in which a silicon nitride surface layer was deposited on silicon nanoparticles, in accordance with the invention. In this example, a silane primary precursor gas (at a flow rate of about 40 sccm) was combined with a helium purge gas (at a flow rate of 2500 sccm) and then flowed into two-stage laser pyrolysis reactor assembly 260, in order to form the core. In addition, an ammonia secondary precursor gas (at a flow rate of about 300 sccm) was also flowed in order to form the shell. The chamber pressure was maintained at about 650 Torr. The laser power was 104 W, with a beam height (H₁ as shown in FIG. 5) of 1.5 mm.

Consequently, it was shown in transmission electron micrograph (TEM) images that adjusting the nozzle height (H₂ of FIG. 5) to about 4 mm produced grafted Group IV nanoparticles that did not significantly dissolve in 1 M KOH. In contrast, adjusting the nozzle height (H₂ of FIG. 5) to about 5.25 mm produced grafted Group IV nanoparticles that did significantly dissolve in 1 M KOH. This example demonstrates the significance of factors such as the height adjustment of the nozzles and the laser beam in producing high quality Group IV nanoparticle materials.

Organically capped material can be prepared using the two-stage laser pyrolysis reactor apparatus described for this example, in combination with a secondary precursor delivery assembly, such as the secondary precursor delivery assembly 220 of FIG. 3, and described in the example given in the above for the preparation of Group IV nanoparticles with organic capping using a two-stage RF reactor. In preparing stably passivated Group IV nanoparticles with an organic capping agent using the laser pyrolysis reactor described in this section for the preparation of the silicon core/silicon nitride shell nanoparticles, instead of using ammonia in the secondary precursor gas stream, a gas stream of short chain (C2-C9) terminal alkene could be used at between about 10 sccm to about 1000 sccm of organic vapor.

While principles of the disclosed in situ modification of Group IV nanoparticles using gas phase reactors have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. A method for creating an organically capped Group IV semiconductor nanoparticle, comprising:
flowing a Group IV semiconductor precursor gas into a chamber;
generating a set of Group IV semiconductor precursor radical species from the Group IV semiconductor precursor gas with a laser pyrolysis apparatus, wherein the set of the Group IV semiconductor precursor radical species nucleate to form the Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

2. The method of claim 1, wherein the Group IV semiconductor precursor gas is one of silane, disilane, germane, and digermane.

3. The method of claim 1, wherein the organic capping agent precursor gas includes at least one of an alkene, an alkyne, an amine, a phenyl, and a benzyl.

4. The method of claim 1, wherein the organically capped Group IV semiconductor nanoparticle has a diameter of between about 1 nm and about 100 nm.

5. The method of claim 1, wherein the organically capped Group IV semiconductor nanoparticle is one of a single-crystalline nanoparticle, a polycrystalline nanoparticle, and an amorphous nanoparticle.

6. A method for creating an organically capped Group IV semiconductor nanoparticle, comprising:
flowing a Group IV semiconductor precursor gas into a chamber;
flowing a dopant precursor gas into the chamber;
generating a set of Group IV semiconductor precursor radical species from the Group IV semiconductor precursor gas and the dopant precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

7. The method of claim 6, wherein the Group IV semiconductor precursor gas is one of silane, disilane, germane, and digermane.

8. The method of claim 6, wherein the dopant precursor gas is one of boron diflouride, trimethyl borane, and diborane.

9. The method of claim 6, wherein the organic capping agent precursor gas includes at least one of an alkene, an alkyne, an amine, a phenyl, and a benzyl.

10. The method of claim 6, wherein the organically capped Group IV semiconductor nanoparticle has a diameter of between about 1 nm and about 100 nm.

11. The method of claim 6, wherein the organically capped Group IV semiconductor nanoparticle is one of a single-crystalline nanoparticle, a polycrystalline nanoparticle, and an amorphous nanoparticle.

12. An organically capped Group IV semiconductor nanoparticle, created by the method comprising:
flowing a Group IV semiconductor precursor gas into a chamber;
generating a set of Group IV semiconductor precursor radical species from the Group IV semiconductor precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

13. The organically capped Group IV semiconductor nanoparticle of claim 12, wherein the Group IV semiconductor precursor gas is one of silane, disilane, germane, and digermane.

14. The organically capped Group IV semiconductor nanoparticle of claim 12, wherein the organic capping agent precursor gas includes at least one of an alkene, an alkyne, an amine, a phenyl, and a benzyl.

15. The organically capped Group IV semiconductor nanoparticle of claim 12, wherein the organically capped Group IV semiconductor nanoparticle has a diameter of between about 1 nm and about 100 nm.

16. The organically capped Group IV semiconductor nanoparticle of claim 12, wherein the organically capped Group IV semiconductor nanoparticle is one of a single-crystalline nanoparticle, a polycrystalline nanoparticle, and an amorphous nanoparticle.

17. An organically capped Group IV semiconductor nanoparticle, created by the method comprising:
flowing a Group IV semiconductor precursor gas into a chamber;
flowing a dopant precursor gas into the chamber;
generating a set of Group IV semiconductor precursor radical species from the Group IV semiconductor precursor gas and the dopant precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

18. The organically capped Group IV semiconductor nanoparticle of claim 17, wherein the Group IV semiconductor precursor gas is one of silane, disilane, germane, and digermane.

19. The organically capped Group IV semiconductor nanoparticle of claim 17, wherein the dopant precursor gas is one of boron diflouride, trimethyl borane, and diborane.

20. The organically capped Group IV semiconductor nanoparticle of claim 17, wherein the organic capping agent precursor gas includes at least one of an alkene, an alkyne, an amine, a phenyl, and a benzyl.

21. The organically capped Group IV semiconductor nanoparticle of claim 17, wherein the organically capped Group IV semiconductor nanoparticle has a diameter of between about 1 nm and about 100 nm.

22. The organically capped Group IV semiconductor nanoparticle of claim 17, wherein the organically capped Group IV semiconductor nanoparticle is one of a single-crystalline nanoparticle, a polycrystalline nanoparticle, and an amorphous nanoparticle.
